(19) United States
(12) Patent Application Publication
(10) Pub. No.: US 2021/0083160 A1
(43) Pub. Date: Mar. 18, 2021

(54) Semiconductor Device and Method for Producing a Carrier Element Suitable for a Semiconductor Device

(71) Applicant: OSRAM Opto Semiconductors GmbH, Regensburg (DE)

(72) Inventors: Choo Kean Lim, Penang (MY); Choon Keat Or, Penang (MY); Siew Yan Chua, Penang (MY); Choon Kim Lim, Penang (MY)

(21) Appl. No.: 16/769,866

(22) PCT Filed: Dec. 14, 2017
(86) PCT No.: PCT/EP2017/082814

§ 371 Date: Jun. 4, 2020

(51) Int. Cl. H01L 33/62; H01L 23/00; H01L 33/64

(52) U.S. Cl. CPC H01L 33/62; H01L 33/642; H01L 24/48

(57) ABSTRACT

A semiconductor device and a method for producing a carrier element suitable for a semiconductor device are disclosed. In an embodiment a semiconductor device includes a carrier element including a carrier layer having a first depression extending from a first main surface of the carrier layer in a direction of a second main surface of the carrier layer opposite the first main surface and a metal substrate and an electrically insulating layer on at least a portion of the metal substrate, a first electrically conductive filling component arranged in the first depression in a form-fitting manner, the electrically insulating layer being arranged between the metal substrate and the first filling component and a semiconductor chip arranged on the carrier element, wherein the electrically insulating layer is an anodization layer.

This patent application is a national phase filing under section 371 of PCT/EP2017/082814, filed Dec. 14, 2017, of which is incorporated herein by reference in its entirety.

### TECHNICAL FIELD

A semiconductor device comprising a carrier element providing for good thermal management is specified. Furthermore, a method for producing a carrier element providing for good thermal management in a semiconductor device is specified.

### BACKGROUND

An existing technology to improve thermal management in LED packages is the insertion of a metal slug into a substrate of the LED package. The substrate, which may be for example a leadframe, a ceramic or printed circuit board, needs to be structured in order to form a cavity where to insert the metal slug. The size of the cavity has to be precise so that the metal slug fits in with tight tolerance. Moreover, the whole slug insertion process is time consuming and leads to high process costs. This problem might be addressed by using a thicker metal slug. However, this would increase the overall package height.

### SUMMARY

Embodiments provide a semiconductor device with a compact size and good thermal management.

Further embodiments provide a method for producing a carrier element providing for good thermal management in a compactly sized semiconductor device.

According to at least one embodiment, the semiconductor device comprises a carrier element and a semiconductor chip arranged on the carrier element. The carrier element has in particular a first main surface, a second main surface opposite to the first main surface and at least one side surface, which connects the first and second main surfaces. The number of side surfaces is determined by the geometry of the carrier element. For example, the carrier element may have the shape of a cuboid. In this case, the element has four side surfaces. The at least one side surface is preferably arranged largely transversely to the first and second main surfaces. “Transversely” means that a normal vector of the side surface is not parallel to a normal vector of the first and/or second main surface. Preferably, the at least one side surface limits the carrier element in one or more lateral directions. The lateral directions are arranged in a plane whose normal vector is arranged parallel to a vertical direction. In particular, the direction in which the semiconductor chip is arranged on the carrier element denotes a vertical direction. Preferably, the first and second main surfaces limit the carrier element in vertical directions. Especially, the semiconductor chip is mounted on the first main surface of the carrier element.

According to at least one embodiment, the carrier element comprises a carrier layer, wherein the carrier layer comprises a first depression. It is also possible for the carrier layer to comprise several first depressions. In particular, the at least one first depression extends from a first main surface of the carrier layer in the direction of a second main surface opposite the first main surface. Especially, the first main surface of the carrier layer is parallel to the first main surface of the carrier element and the second main surface of the carrier layer is parallel to the second main surface of the carrier element. Extending from the first main surface of the carrier layer in the direction of the second main surface of the carrier layer means that the depression either partly or completely penetrates the carrier layer from the first main surface to the second main surface. In a preferred configuration, the first depression is a through-hole completely penetrating the carrier layer in the vertical direction. Moreover, the first depression may be completely or partly laterally surrounded by the carrier layer.

According to at least one embodiment, the carrier layer comprises a metal substrate. A “metal substrate” is to be understood as a substrate which is formed from a metal or a metal compound and is characterized by at least one of the following properties: high electrical conductivity, which decreases with increasing temperature; high thermal conductivity; ductility; mirror gloss. Especially, the metal substrate is made of a metal or a metal alloy. Suitable materials for the metal substrate are, for example, aluminium or aluminium alloys. An aluminium-based metal substrate has the advantage that it is of low weight.

According to at least one embodiment, the carrier layer comprises an electrically insulating layer on at least a portion of the metal substrate. Especially, an area of the metal substrate facing the first depression is completely covered by the electrically insulating layer, whereas other portions of the metal substrate may be free of the electrically insulating layer. Preferably, the carrier layer consists of the metal substrate and the electrically insulating layer.

Preferably, the electrically insulating layer is an anodization layer. The anodization layer is a compound layer formed by an anodization process, which is a chemical conversion process where the material of the metal substrate is converted into a compound of the material of the metal substrate. Especially, the electrically insulating layer is an oxidized layer of the metal or metal alloy of the metal substrate. For example, the electrically insulating layer is an oxidized layer of aluminium or an aluminium alloy. The anodization process advantageously involves a substance-to-substance bond between the anodization layer and the metal substrate resulting in a mechanically stable connection between the electrically insulating layer and the metal substrate.

According to at least one embodiment, the carrier element comprises a first electrically conductive filling component arranged in the first depression in a form-fitting manner. In particular, the form-fitting arrangement of the first electrically conductive filling component in the first depression can be achieved by electrodeposition of the filling component in an electroplating process. In other words, the first electrically conductive filling component preferably is electrodeposited in the depression. Especially, the first filling component serves as a heat sink. The electrodeposition allows for an economic fabrication method of the filling component or of the heat sink. Moreover, the integration of the heat sink into the carrier layer allows for a compact package design.

Preferably, the first filling component does not protrude over the first main surface of the carrier layer. The first filling component may partly or completely fill the first depression. Especially, a first surface of the first filling component terminates flush with the first main surface of the carrier layer. Moreover, a second surface of the first filling component may terminate flush with the second main surface of the carrier layer. The first surface of the first filling component is arranged at the first main surface of the carrier element, whereas the second surface of the first filling component is arranged at the second main surface of the carrier element. The first filling component may be completely laterally surrounded by the carrier layer. In this case, the side surfaces of the carrier element are formed by side surfaces of the carrier layer. Alternatively, the first filling component may be partly laterally surrounded by the carrier layer such that at least one side surface of the carrier element is partly formed by a surface of the first filling component.

According to at least one embodiment, the electrically insulating layer is arranged between the metal substrate and the first filling component. Thus, the metal substrate and the first filling component are electrically isolated by the electrically insulating layer and no remarkable electric current flows between the metal substrate and the first filling component.

In a preferred configuration of the semiconductor device, the metal substrate is completely covered by the electrically insulating layer. As a consequence, the metal substrate is completely electrically isolated. The overall coverage of the metal substrate by the electrically insulating layer improves its corrosion resistance.

The preferred thickness of the electrically insulating layer ranges from about 30 microns to about 70 microns. The most preferred thickness is in the range of from about 35 microns to about 65 microns. The electrically insulating layer having a thickness in this range may withstand voltages from about 100 V to 200 V.

In a further configuration of the semiconductor device, the first electrically conductive filling component comprises or consists of metal. Especially, the first filling component has the metal properties as mentioned above and consists of a metal, a metal compound or a metal sequence. Preferably, the first filling component comprises or consists of copper. Copper or a copper alloy are preferred materials due to their high thermal conductivity.

According to at least one embodiment, the semiconductor chip is mounted on a first surface of the first filling component. Preferably, the first surface laterally projects over the semiconductor chip. This has the advantage that the first filling component works as a heatspreader which distributes the punctual heat of the semiconductor chip over a larger area and thus provides for an effective cooling of the semiconductor chip.

According to an advantageous configuration, the lateral size of the first filling component decreases discontinuously from the first main surface to the center of the carrier element in at least one lateral direction, preferably in all lateral directions. Preferably, the first filling component comprises at least one first region and at least one second region, wherein the first region follows the second region in the vertical direction and has a greater lateral size than the second region. Moreover, the first filling component may increase discontinuously from the center of the carrier element to the second main surface. For example, the first filling component may comprise a second region arranged between two first regions, wherein one first region is arranged at the first main surface and another first region is arranged at the second main surface of the carrier element. This structure of the first filling component allows for good anchoring of the same within the carrier layer. In particular, the first filling component has a rotationally symmetrical three-dimensional shape. For example, the first filling component may be composed of at least one cylinder or cuboid.

Moreover, the smaller a vertical size of the first region, the bigger is the lateral size of the second region. Thus, constantly good heat spreading can be achieved.

According to at least one embodiment, the carrier layer comprises at least one second depression extending from the first main surface of the carrier layer in a direction of the second main surface of the carrier layer opposite the first main surface. Moreover, the carrier element may comprise a second electrically conductive filling component arranged in a form-fitting manner in the second depression of the carrier layer. The second filling component may differ from the first filling component in its lateral size. Especially, the first filling component has a greater lateral size than the second filling component. Whereas the first surface of the first filling component inter alia serves as a mounting area and heat sink for the semiconductor chip, a first surface of the second filling component preferably serves as a connection area for electrically connecting the semiconductor chip and thus may be smaller than the first surface of the first filling component. With respect to its structure and material, the second electrically conductive filling component is preferably identical to the first electrically conductive filling component.

In an advantageous configuration, the carrier element comprises a structured cover layer, which may overlay the first surface of the first and/or second filling component and/or a second surface of the first and/or second filling component. Preferably, the cover layer is a metal layer or a metal layer sequence. In particular, the cover layer may comprise or consist of Au, Pt, Pd or Ni. For example, the cover layer may comprise a layer sequence of Ni/Au, Ni/Pd/Au or Ni/Pd. It is possible to produce the cover layer by an electrolytic or electroless plating method.

According to at least one embodiment, the first filling component is a first electric terminal of the semiconductor device and the second filling component is a second electric terminal of the semiconductor device. Especially, the semiconductor device is surface-mountable, wherein the second surfaces of the filling components are provided for electrically and mechanically connecting the semiconductor device to a circuit board.

In accordance with at least one embodiment, the semiconductor chip comprises a semiconductor body having a first semiconductor region and a second semiconductor region. Furthermore, the semiconductor body has a first main area and a second main area opposite the first main area. In particular, the first main area and the second main area delimit the semiconductor body in vertical directions. The first semiconductor region may have a first conductivity and the second semiconductor region may have a second conductivity. Preferably, the first semiconductor region is a p-type semiconductor region. Furthermore, the second semiconductor region is, in particular, an n-type semiconductor region. The first and second semiconductor regions may each comprise a semiconductor layer sequence. In this case, it is possible for the first semiconductor region and the second semiconductor region to contain doped and one or more undoped layers.

The first and second semiconductor regions can be produced in layers one after the other on a growth substrate by means of an epitaxy process, wherein preferably the second semiconductor region is applied to the growth substrate first and the first semiconductor region is then applied to the second semiconductor region. Suitable materials for the growth substrate are, for example, sapphire, SiC and/or GaN. The growth substrate can be at least partially removed after the production of the semiconductor body, so that the second main area or a surface of the second semiconductor region is at least partially exposed. An alternative substrate may be used as a chip carrier in the semiconductor chip.

According to a preferred embodiment, the semiconductor chip is an optoelectronic, especially a radiation-emitting semiconductor chip. In particular, the semiconductor body comprises an active zone which is suitable for generating radiation or for radiation detection. In particular, the active zone is a p-n transition zone. The active zone may be formed as a layer or as a layer sequence of several layers. During operation of the semiconductor chip, the active zone may emit electromagnetic radiation in the visible, ultraviolet or infrared spectral range. Alternatively, during operation of the semiconductor chip, the active zone may absorb electromagnetic radiation and convert it into electrical signals or electrical energy. The active zone is in particular arranged between the first semiconductor region and the second semiconductor region. A substantial portion of the radiation generated or absorbed by the active zone preferably passes through the first main area of the semiconductor body.

The layers of the semiconductor body preferably contain at least one III/V semiconductor material, for example a material from the material systems InxGayAl1-x-yP, InxGayAl1-x-yN or InxGayAl1-x-yAs, in each case with 0≤x, y≤1 and x+y≤1. III/V semiconductor materials are used for radiation generation in the ultraviolet (InxGayAl1-x-yN), over the visible (InxGayAl1-x-yN, especially for blue to green radiation, or InxGayAl1-x-yP, especially for yellow to red radiation) down to the infrared (InxGayAl1-x-yAs) spectral range.

Furthermore, the semiconductor chip may comprise a first electrode and a second electrode, which are provided for electrically contacting the semiconductor body, wherein the first electrode may form a p-contact and the second electrode may form an n-contact. In particular, the first electrode is arranged on the first main area of the semiconductor body and the second electrode is arranged on the second main area of the semiconductor body. The electrodes are electrically conductive layers, for example. Especially, the second electrode is electrically connected to the first filling component. And the first electrode may be electrically connected to the second filling component.

According to an advantageous configuration, the semiconductor device is mounted to the carrier element by an attachment layer, particularly by a die attach. The attachment layer may be electrically conductive or electrically insulating dependent upon the needs of the semiconductor device. Moreover, the first electrode may be electrically connected to the second filling component by a wire bond.

According to at least one embodiment of a method for producing a carrier element suitable for a semiconductor device, the method comprises the following steps:

providing a metal substrate,

producing a first depression in the metal substrate,

producing an electrically insulating layer on at least a portion of the metal substrate,

at least partly electrodepositing a first electrically conductive filling component in the first depression in a form-fitting manner, wherein the electrically insulating layer is arranged between the metal substrate and the first filling component, wherein the electrically insulating layer is produced by anodizing at least a portion of the metal substrate.

For producing a plurality of carrier elements, a metal substrate assembly may be used, and several first depressions are formed in the metal substrate assembly. All further method steps may be conducted in accordance with the method steps described in connection with the production of one carrier element.

The anodization is a conversion process which may be conducted by applying an aqueous solution containing, for example, sulfuric acid at about room temperature on the surface of the anodically charged metal substrate. Preferably, the anodization is conducted after formation of the first depression. Preferably, the first depression is produced by punching or drilling the metal substrate.

According to at least one embodiment of the method, producing the first filling component may involve a first step of producing a seed layer on the surface which laterally delimits the first depression. The seed layer may be a metal layer which is sputtered on the respective surface. For example, the seed layer may contain one of the materials Cu, Au, Ti or Pt or consist of one of these materials. Furthermore, producing the first filling component may involve a second step of applying a metallization to the seed layer, preferably by means of an electroplating process. Especially, the metallization contains or consists of copper or a copper alloy. The filling component then is composed of the seed layer and the metallization.

In an advantageous embodiment of the method, a second depression is produced in the metal substrate and a second filling component is arranged in the second depression. Preferably, the production of the second depression and the second filling component can be conducted in accordance with the production of the first depression and the first filling component. Especially, the production of the first and second depression(s) and/or the first and second filling component(s) can be conducted simultaneously.

In a preferred method of producing a semiconductor device as specified above, a carrier element as described above is provided and a semiconductor chip is mounted to the first surface of the first filling component, for example by a die attach process.

The features described in connection with the semiconductor device can also be applied to the method and vice versa.

### BRIEF DESCRIPTION OF THE DRAWINGS

Further advantages, advantageous embodiments and further developments become clear from the exemplary embodiments described in the following in connection with the figures.

FIGS. 1 and 2 show schematic sectional views of semiconductor devices according to different exemplary embodiments; and

FIGS. 3 to 7 show schematic sectional views of various method steps of a method for producing a carrier element according to an exemplary embodiment of a method, and FIGS. 3 to 8 show schematic sectional views of various method steps of a method for producing a semiconductor device according to an exemplary embodiment of a method.

### DETAILED DESCRIPTION OF ILLUSTRATIVE EMBODIMENTS

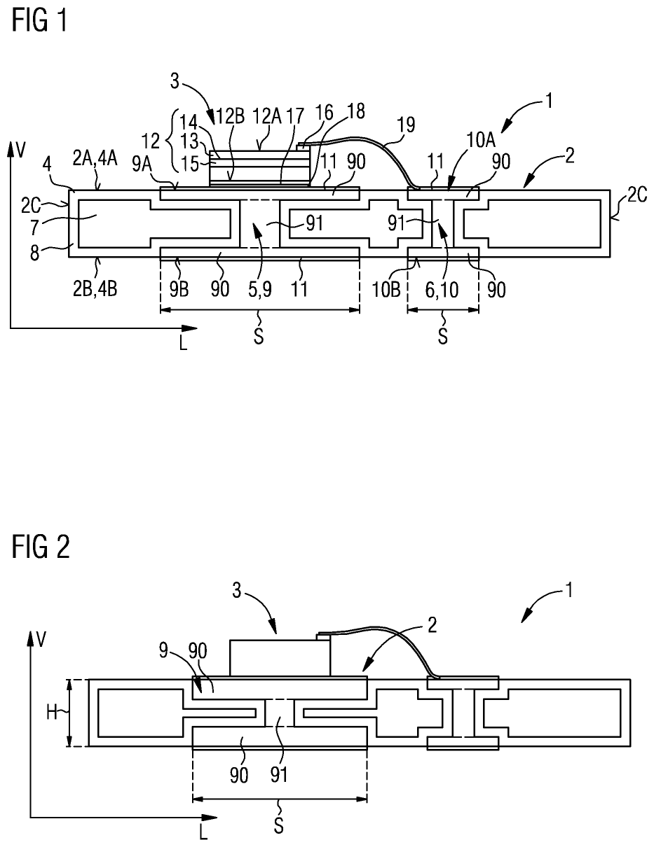

FIG. 1 shows a first exemplary embodiment of a semiconductor device 1, which preferably is a radiation-emitting device. The semiconductor device 1 comprises a carrier element 2 and preferably a radiation-emitting semiconductor chip 3 arranged on the carrier element 2. The carrier element 2 has a first main surface 2A, a second main surface 2B opposite the first main surface 2A and side surfaces 2C, which connect the first and second main surfaces 2A, 2B.

The carrier element 2 comprises a carrier layer 4, which has a first depression 5 extending from a first main surface 4A of the carrier layer 4 in a direction of a second main surface 4B of the carrier layer 4 opposite the first main surface 4A and has a second depression 6 extending from the first main surface 4A in the direction of the second main surface 4B. In particular, the first and second depressions 5, 6 are through-holes completely penetrating the carrier layer 4. The carrier layer 4 further comprises a metal substrate 7 and an electrically insulating layer 8 on the whole metal substrate 7. Especially, the carrier layer 4 consists of the metal substrate 7 and the electrically insulating layer 8. The electrically insulating layer 8 is an anodization layer, which is made of a compound of the material of the metal substrate 7. Preferably, the metal substrate 7 comprises or consists of aluminium or aluminium alloys, and the electrically insulating layer 8 is an oxidized layer of aluminium or an aluminium alloy.

The carrier element 2 comprises a first electrically conductive filling component 9 arranged in the first depression 5 in a form-fitting manner and a second electrically conductive filling component 10 arranged in the second depression 6 in a form-fitting manner. The first and second electrically conductive filling components 9, 10 are each at least partly electrodeposited in the depressions 5, 6. Especially, the first filling component 9 serves as a heat sink. And the electrodeposition allows for an economic fabrication method of the heat sink. The first and second electrically conductive filling components 9, 10 comprise or consist of metal. Preferably, the filling components 9, 10 comprise or consist of copper. The filling components 9, 10 can be made of different or the same materials.

Preferably, the first and second filling components 9, 10 do not protrude over the first main surface 4A of the carrier layer 4. Especially, first surfaces 9A, 10A of the first and second filling components 9, 10 terminate flush with the first main surface 4A of the carrier layer 4. Moreover, the first and second filling components 9, 10 may not protrude over the second main surface 4B of the carrier layer 4. Especially, second surfaces 9B, 10B of the first and second filling components 9, 10 terminate flush with the second main surface 4B of the carrier layer 4. This integration of the heat sink into the carrier layer 4 allows for a compact and small package design.

Both the first and the second filling components 9, 10 have a lateral size S measured along a first lateral direction L which decreases discontinuously from the first main surface 4A to a center of the carrier element 2 and increases discontinuously from the center to the second main surface 4A. The filling components 9, 10 each comprise a second region 91 arranged between two first regions 90 in the vertical direction V, wherein one first region 90 is arranged at the first main surface 2A and another first region 90 is arranged at the second main surface 2B of the carrier element 2 and wherein the first regions 90 have a greater lateral size S than the second region 91. This structure of the filling components 9, 10 allows for good anchoring of the same within the carrier layer 4. Both the first and the second filling components 9, 10 may have a lateral size measured along a second lateral direction (not shown) running perpendicular to the vertical and first lateral directions V, L which is constant along the vertical direction V or may vary. The first and second regions 90, 91 may be cylinders or cuboids of different lateral sizes S.

The first and second filling components 9, 10 differ from each other in their lateral sizes S. In other words, the maximum lateral size S of the first filling component 9 is greater than the maximum lateral size S of the second filling component 10.

The electrically insulating layer 8 is arranged between the metal substrate 7 and the respective filling component 9, 10. Here, not only areas of the metal substrate 7 facing the first and second depressions 5, 6 are completely covered by the electrically insulating layer 8, but the whole metal substrate 7 is covered by the electrically insulating layer 8. The overall coverage of the metal substrate 7 by the electrically insulating layer 8 improves the corrosion resistance of the carrier layer 4.

The carrier element 2 comprises a structured cover layer 11, which overlays the first surfaces 9A, 10A and the second surfaces 9B, 10B of the first and second filling components 9, 10. Preferably, the cover layer 11 is a metal layer or metal layer sequence comprising or consisting of a metal like Au, Pd, Pt or Ni. For example, the cover layer 11 may comprise a layer sequence of Ni/Au, Ni/Pd/Au or Ni/Pd.

The semiconductor chip 3 is mounted on the first surface 9A of the first filling component 9, wherein the first surface 9A is arranged at a first main surface 2A of the carrier element 2. The first surface 9A laterally projects over the semiconductor chip 3. This has the advantage that the first filling component 9 works as a heatspreader which distributes the punctual heat of the semiconductor chip 3 over a larger area and thus provides for an effective cooling of the semiconductor chip 3. Moreover, the first filling component 9 is a first electric terminal of the semiconductor device 1 and the second filling component 10 is a second electric terminal of the semiconductor device 1.

The semiconductor chip 3 comprises a semiconductor body 12 having a first semiconductor region 13 and a second semiconductor region 15 and an active zone 14 for generating radiation during operation arranged between the first and second semiconductor regions 13, 15. Furthermore, the semiconductor body 12 has a first main area 12A and a second main area 12B opposite the first main area 12A. Preferably, the first semiconductor region 13 is a p-type semiconductor region and the second semiconductor region 15 is an n-type semiconductor region.

The semiconductor chip 3 comprises a first electrode 16 and a second electrode 17, which are provided for electrically contacting the semiconductor body 12, wherein the first electrode 16 forms a p-contact and the second electrode 17 forms an n-contact. The first electrode 16 is arranged on the first main area 12A of the semiconductor body 12 and the second electrode 17 is arranged on the second main area 12B of the semiconductor body 12, wherein the electrodes 16, 17 are electrically conductive layers. The second electrode 17 is electrically connected to the first filling component 9, and the first electrode 16 is electrically connected to the second filling component 10. Especially, the semiconductor device 1 is mechanically and electrically connected to the carrier element 2 by an attachment layer 18. Moreover, the first electrode 16 is electrically connected to the second filling component 10 by a wire bond 19.

FIG. 2 shows a second exemplary embodiment of a semiconductor device 1, which has a similar structure as the first exemplary embodiment. However, according to the second exemplary embodiment, the first regions 90 of the first filling component 9 have a greater vertical size H than the first regions 90 of the first filling component 9 according to the first exemplary embodiment. Moreover, according to the second exemplary embodiment, the second region 91 of the first filling component 9 has a smaller lateral size S than the second region 91 of the first filling component 9 according to the first exemplary embodiment.

Both embodiments provide for good heat spreading and show that, the smaller a vertical size H of the first region 90, the bigger is the lateral size S of the second region 91.

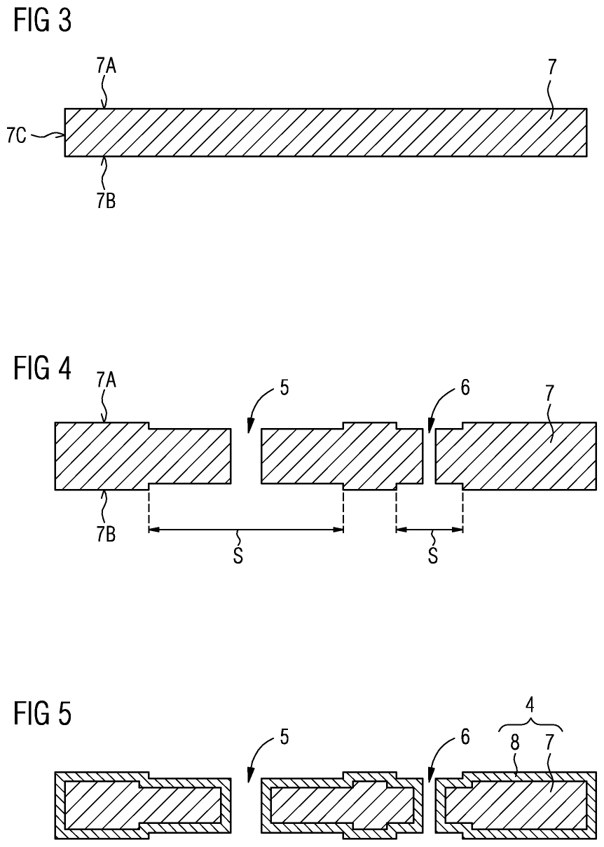

A method for producing a carrier element 2 or a semiconductor device 1 is described in connection with FIGS. 3 to 8.

First (see FIG. 3), a metal substrate 7 is provided. The metal substrate 7 has a cuboid shape and comprises a planar first main surface 7A and a planar second main surface 7B opposite the first main surface 7A as well as several side surfaces 7C.

Then (see FIG. 4), a first depression 5 and a second depression 6 are formed in the metal substrate 7 such that they completely penetrate the metal substrate 7 and are at least partly surrounded by the metal substrate 7. The first and second depressions 5, 6 are each formed with the lateral sizes S decreasing discontinuously from the first main surface 7A to the center of the metal substrate 7 and increasing discontinuously from the center of the metal substrate 7 to the second main surface 7B. The first and second depressions 5, 6 can be produced by punching or drilling the metal substrate 7.

Next (see FIG. 5), an electrically insulating layer 8 is produced on the whole metal substrate 7 by anodizing the metal substrate 7 in the depressions 5, 6 and at all surfaces 7A, 7B, 7C. For the anodization an aqueous solution containing, for example, sulfuric acid is applied at about room temperature to the depressions and on the surfaces 7A, 7B, 7C of the anodically charged metal substrate 7. The advantage of this process is that the lateral and vertical sizes of the depressions 5, 6 remain constant and are not influenced by the production of the electrically insulating layer 8. The metal substrate 7 and the electrically insulating layer 8 together form a carrier layer 4.

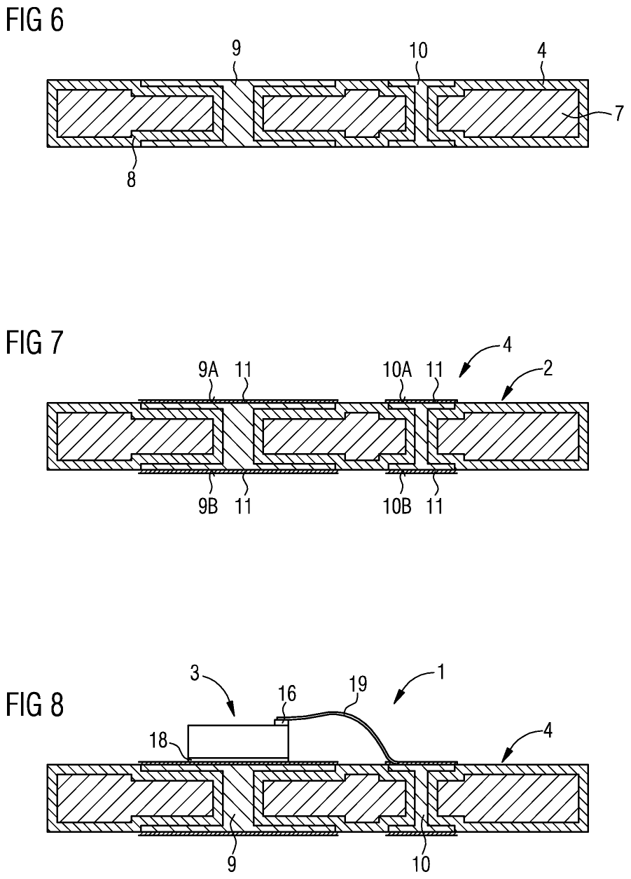

Afterwards (see FIG. 6), a first electrically conductive filling component 9 is produced in the first depression 5 in a form-fitting manner, wherein the electrically insulating layer 8 is arranged between the metal substrate 7 and the first filling component 9. And a second electrically conductive filling component 10 is produced in the second depression 6 in a form-fitting manner, wherein the electrically insulating layer 8 is arranged between the metal substrate 7 and the second filling component 10. In particular, the first and second filling components 9, 10 may be produced by an electroplating process. For example, producing the first and second filling components 9, 10 may involve a first step of producing a seed layer on the surface which laterally delimits the depressions 5, 6. The seed layer may be a metal layer which is sputtered on the respective surface. In a second step a metallization may be applied to the seed layer, by electrodeposition in an electroplating process.

Next (see FIG. 7), a structured cover layer 11 is produced, for example by electrolytic or electroless plating. Especially, the cover layer 11 is formed to overlay the first surfaces 9A, 10A of the first and second filling components 9, 10 and the second surfaces 9B, 10B of the first and second filling components 9, 10. The so produced element is a carrier element 2 suitable for a semiconductor device 1.

In order to produce a semiconductor device 1 (see FIG. 8), a carrier element 2 as described above is provided and a semiconductor chip 3 is mounted on the first surface 9A of the first filling component 9 by a die attach process, wherein an attachment layer 18 is used between the semiconductor chip 3 and the carrier element 2. A wire bonding process is carried out in order to electrically connect the first electrode 16 of the semiconductor chip 3 to the second filling component 10.

The scope of protection of the invention is not limited to the examples given hereinabove. The invention is embodied in each novel characteristic and each combination of characteristics, which particularly includes every combination of any features which are stated in the claims, even if this feature or this combination of features is not explicitly stated in the claims or in the examples.

1-15. (canceled)

16. A semiconductor device comprising:
a carrier element comprising:
a carrier layer comprising:
a first depression extending from a first main surface of the carrier layer in a direction of a second main surface of the carrier layer opposite the first main surface; and
a metal substrate and an electrically insulating layer on at least a portion of the metal substrate;
a first electrically conductive filling component arranged in the first depression in a form-fitting manner, the electrically insulating layer being arranged between the metal substrate and the first filling component; and
a semiconductor chip arranged on the carrier element, wherein the electrically insulating layer is an anodization layer.

17. The semiconductor device according to claim 16, wherein the metal substrate is made of a metal or a metal alloy and the electrically insulating layer is an oxidized layer of the metal or metal alloy of the metal substrate.

18. The semiconductor device according to claim 16, wherein the metal substrate is made of aluminium or an aluminium alloy and the electrically insulating layer is an oxidized layer of aluminium or an aluminium alloy.

19. The semiconductor device according to claim 16, wherein the metal substrate is completely covered by the electrically insulating layer.

20. The semiconductor device according to claim 16, wherein the first filling component comprises a metal.

21. The semiconductor device according to claim 16, wherein the first filling component consists essentially of copper.

22. The semiconductor device according to claim 16, wherein the first filling component is at least partly electrodeposited in the depression.

23. The semiconductor device according to claim 16, wherein the first depression is a through-hole completely penetrating the carrier layer.

24. The semiconductor device according to claim 16, wherein the semiconductor chip is mounted on a first surface of the first filling component, the first surface laterally projecting over the semiconductor chip.

25. The semiconductor device according to claim 16, wherein the first filling component comprises at least one first region and at least one second region, and wherein the first region follows the second region in a vertical direction and has a greater lateral size than the second region.

26. The semiconductor device according to claim 16, wherein the carrier element comprises a second electrically conductive filling component arranged in a form-fitting manner in a second depression of the carrier layer, and wherein the first filling component has a greater lateral size than the second filling component.

27. The semiconductor device according to claim 26, wherein the first filling component is a first electric terminal of the semiconductor device and the second filling component is a second electric terminal of the semiconductor device.

28. The semiconductor device according to claim 16, wherein the carrier element comprises a structured cover layer overlaying a first surface of the first filling component and/or a second filling component and/or a second surface of the first filling component and/or a second filling component.

29. A method for producing a carrier element suitable for a semiconductor device, the method comprising:
providing a metal substrate;
producing a first depression in the metal substrate;
producing an electrically insulating layer on at least a portion of the metal substrate; and
at least partly electrodepositing a first electrically conductive filling component in the first depression in a form-fitting manner,
wherein the electrically insulating layer is arranged between the metal substrate and the first filling component, and
wherein the electrically insulating layer is produced by anodizing at least a portion of the metal substrate.

30. The method according to claim 29, wherein the first depression is produced by punching or drilling the metal substrate.
